(19) United States
(12) Patent Application Publication
(10) Pub. No.: US 2012/0022792 A1
(43) Pub. Date: Jan. 26, 2012

(54) METHOD OF QUANTIZATION OF MAGNETIC NANOPARTICLE ABSORPTION INTO ANIMAL TISSUES, AND EQUIPMENT FOR DOING IT

(75) Inventors: Roberto Daniel Zysler, San Carlos de Bariloche (AR); Marcelo Vasquez Mansilla, San Carlos de Bariloche (AR); Enio Lima, JR., San Carlos de Bariloche (AR); Pablo Gurman, San Martin (AR); Alberto Lamagna, San Martin (AR)

(73) Assignees: CONSEJO NACIONAL DE INVESTIGACIONES CIENTIFICAS Y TECNICAS (CONICET), Ciudad Autonoma de Bs. As (1033) (AR); COMISION NACIONAL DE ENERGIA ATOMICA (CNEA), Ciudad Autonoma de Bs. As (1429) (AR)

(21) Appl. No.: 13/166,221

(22) Filed: Jun. 22, 2011

(30) Foreign Application Priority Data
Jun. 23, 2010 (AR) ARP-2010-01-02217

(51) Int. Cl. G06F 19/00; G01R 33/02

(52) U.S. Cl. 702/19; 324/244

(57) ABSTRACT

A method of quantization of magnetic nanoparticle absorption in animal tissues includes determination of the number of magnetic nanoparticles absorbed in animal tissues by magnetization measurements. The method is based on the measurement of magnetization versus magnetic field applied of the tissue sample absorbed with the nanoparticles obtaining their saturation magnetization. This magnitude is compared to the saturation magnetization of the same nanoparticles found in the tissue for the determination of the absolute number of magnetic nanoparticles in the animal tissue studied. The method includes preparing the samples for the sample holder, measuring the magnetization vs. applied magnetic field of a known number of magnetic nanoparticles, determining the saturation magnetization of the sample to be studied by measuring the magnetization and calculating the nanoparticle mass in the tissues from the data measured (saturation magnetization of the sample and of calibration of nanoparticles).

### CROSS-REFERENCE TO RELATED U.S. APPLICATIONS

Not applicable.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC

Not applicable.

### BACKGROUND OF THE INVENTION

1. Field of the Invention

The present invention is directed to a method of quantization of magnetic nanoparticle absorption in animal tissues, and to the equipment for doing it. The method comprises determining the number of magnetic nanoparticles (used for medical treatments, protocols and diagnosis) absorbed into animal tissues by magnetization measurements.

The method of the invention is mainly applied in medicine, for the determination of the number of magnetic nanoparticles present in the tissues and with these data doing the research, development and corresponding preparation of the protocols, for administration and use of nanoparticles; for transportation of medication or other biologically active material for a medical treatment, for hyperthermia treatment with magnetic particles, for diagnosis, or in another application that could arise from use of magnetic nanoparticles.

2. Description of Related Art Including Information Disclosed Under 37 CFR 1.97 and 37 CFR 1.98.

Use of magnetic nanoparticles in medicine has aroused a great interest in the scientific community for several reasons such as the possibility of using them for transporting drugs specifically to a site in the organism preventing toxicities, several times unacceptable, such as in cancer chemotherapy. Additionally there is a possibility of using them as therapeutic tools themselves, through the method known as hyperthermia and thermal ablation, wherein the mechanical properties of the particles submitted to an alternate magnetic field are utilized to generate local heat thereby destroying a tumor, without requiring use of drugs. The latter has encouraged increasing study thereof and there already exist commercial products based thereon. Nanoparticles can also be used as contrast agents simultaneously making a treatment, for which there already exist commercial products based on the nanoparticles. All of them are an unequivocal proof of the potential of this kind of particles.

Quantization of nanoparticles in tissues is for the purpose of determining the biodistribution thereof in order to perfect the arrival of the particles to diseased tissues in the organism such as can be the tumor tissue. Quantization of nanoparticles in this kind of tissues is key, for example, in treatments based on these nanoparticles, such as in hypothermia products and in the specific transportation of medicines mediated by these particles, wherein it is needed to quantize the number of nanoparticles in the target tissue and in the remaining healthy tissues. For example, in hypothermia it is esential to control the heat generated both in the diseased and in the healthy tissue, while in the transportation of nanoparticle-based medicines it is required to know the amount of drug that reaches the tumor and the healthy tissues for minimizing the adverse reactions thereof. Ultimately quantizing the number of magnetic nanoparticles in tissues proves to be a valuable tool to perfect the treatments based thereon in terms of a greater effectiveness and a lower toxicity and to determine the protocols needed for use thereof in patients.

Various methods have been developed to identify the magnetite nanoparticles in animal tissue samples. These methods can be classified into qualitative and quantitative methods.

Regarding qualitative methods, colorimetric methods have been very much used. Ferrozine method, using a specific iron chelating agent for changing iron oxidation state and is able to release iron from the magnetite crystal structure. This proves to be a disadvantage since the iron which is a part of hemoglobin is also released and the method loses specificity since it cannot distinguish the source of the iron in the sample. The Prussian blue method uses a potassium ferrocyanide based colorant which when complexing Fe⁺² and Fe⁺³ in its crystal structure generates a blue color due to an energy transfer process between these two species. The problem of the method additionally to being qualitative is that it does no allow to distinguish the iron source and additionally exposure to light can change the reactive color.

Among the methods used used until now for the quantitative determination of the nanoparticles, we can mention use of radioactively tagged iron, Atomic Absorption Spectrometry, ICP (Inductively Coupled Plasma Optical Emission Spectroscopy), ESR (Electron Spin Resonance Spectroscopy), Transmission Electron Microscopy (TEM), Nuclear Magnetic Resonance (NMR) and recently a method of absolute determination of the number of nanoparticles in a tissue by ferromagnetic resonance (FMR) has been introduced.

Atomic Absorption Spectrometry is a technique able to detect the presence of almost any element, since it is sprayed by an energy source as a flame or an electrothermal method. The method is very sensitive, but it is unable to determine whether iron comes from the sample (endogenous iron) or from the magnetic particles, thereby generating a result masking.

Although plasma induction spectroscopy is a quantitative technique, it has the same problems as Atomic Absorption Spectrometry, since it is unable to distinguish endogenous iron (present in proteins as hemoglobin, ferritin, etc.) and exogenous iron (coming from the nanoparticles).

Although iron radioactive tagging (e.g. ⁵⁹Fe) can be detectable with scintillation counter it requires handling of radioactive material, potentially hazardous for health and environment, and additionally incurs in a series of protocols which increase the time and inputs required for their use.

Although the ESR technique is able to distinguish endogenous and exogenous iron, it requires a preparation of the sample due to the recipient's characteristics where the same it is introduced, making preparation thereof a complex process.

Transmission electron microscopy is an extremely expensive tool and which implies a series of steps that make it incompatible with routine measurement of samples and is not always available. Additionally the visualization of the particles can be subject to errors, since some subcellular structures can give images much similar to that of the magnetic nanoparticles. Additionally, obtaining a quantitative result by this technique is very difficult and hard.

The Nuclear Magnetic Resonance method has recently been used to attempt to quantize magnetic nanoparticles. This technique is based on the existing relationship of signal intensity to relaxation times of the proton spins used for NMR tomography imaging. The proportional relationship of the signal obtained by NMR to nanoparticle concentration would exist only in certain situations, which makes the method less reliable.

A method for absolutely determining the number of nanoparticles in a tissue by ferromagnetic resonance (FMR) has been recently introduced [International Journal of Nanomedicine 2010:5 203-211]. This method is very sensitive but it requires a very specific magnetic resonance equipment and a trained staff for interpretation of the spectra obtained in order to get the data searched.

### BRIEF SUMMARY OF THE INVENTION

It can be seen that in most of the scientific works where nanoparticles in animal tissues are used, the data of the number of nanoparticles in the various tissues is not solved, but, at most, the dose injected in the study animal. There is a need to solve this quantization in the simplest and most accurate way possible, since magnetic nanoparticle absorption by the various animal tissues, with their various functions, are essential data for developing research in the subject of medical treatments with magnetic nanoparticles and for designing the required application protocols in patients for their treatment, and they it can even be a stage thereof in order to improve treatment effectiveness and specificity.

The method of the invention deals with determination of the number of magnetic nanoparticles in animal tissues, by magnetization measurements of a known number thereof and of the tissues to be determined.

One of the advantages of the invention is that the measurement gives a quantization of the number of nanoparticles without interference of the iron coming from hemoglobin and requires very small amounts of tissue for such purpose.

Another advantage of the method of the invention is its easy implementation and interpretation its main application being in medical routine measurements. Any magnetic signal excitation and detection unit (magnetometer) would allow this process and in the case of the “ad hoc” magnetization measuring equipment it is very simple since it consists of a small magnetometer working at moderate magnetic fields (perhaps with permanent magnets or electromagnets) and additionally emphasizing as another advantageous characteristic that measurements are made at room temperature.

In a particular application this determination of the number of nanoparticles can be standardized with the total mass of the sample thus giving an intensive characteristic of the material. This intensive characteristic would allow to determine several characteristics regarding the relationship of nanoparticles to tissues, giving essential data for developing research in the subject of medical treatments.

### BRIEF DESCRIPTION OF THE INVENTION

The method of the invention is based on the following concepts:

Superparamagnetic nanoparticles consist of a single domain whose magnetic moments can be rapidly inverted as a result of the thermal energy without applying a magnetic field. If an external magnetic field is applied, the magnetic moment of the particles tends to align in the direction of the field giving a net magnetization for the system. The magnetization of the nanoparticle system depends not only on the application of magnetic field H, but also on temperature T. Magnetization vs. magnetic field and temperature M(H, T) is given by Langevin function, L(x):

M(H,T)=M_{S}L(H,T);

wherein M_{S} is saturation magnetization,

$$x = \frac{μ H}{{k}_{B} T} , μ$$

is the nanoparticle magnetic moment and k_{B} is Boltzmann constant. The magnetization curves at different temperatures, typical of a superparamagnetic system, are plotted in FIG. 1. The universality of these curves is evident since all curves superimpose when they are plotted versus H/T (insert in FIG. 1). The pertinente curve parameters M(H,T) are saturation magnetization and nanoparticle magnetic moment, which changes its curvature. Saturation magnetization MS is an intrinsic property of the material, generally standardized in mass (emu/g) or volume (emu/cm³), being 1000 emu=1 Am². Measuring the value of M_{S} of a sample gives exactly the amount of the magnetic phase in the entire sample. Saturation magnetization of nanoparticle systems has values lower than the value of M_{S} of the massive material with the same composition. It should be considered that a previous characterization of magnetic nanoparticles is required for the quantization method of the invention.

Additionally, organic materials present in animal tissues generally show a diamagnetic behavior or, sometimes, a paramgnetic behavior. It is known that, by applying a magnetic field, the behavior of hemoglobin is diamagnetic or paramagnetic versus oxygenation degree thereof. The characteristic curve M(H) of diamagnetic (paramagnetic) materials before application of moderate magnetic fields corresponds to a linear behavior with a negative (positive) slope as represented in FIG. 2(a). This slope is the magnetic susceptibility (X) of the material. The difference among magnetization curves of the magnetic nanoparticles and the animal tissue allows us to easily separate the contributions of each component of a system consisting of organic tissue+magnetic particles. In FIG. 2(b) the expected magnetization curve for a system consisting of a superparamagnetic nanoparticle dispersion diluted in a diamagnetic tissue, has been represented, by way of example, wherein the saturation magnetization of the superparamagnetic phase is clearly obtained by extrapolation of magnetization of high magnetic fields at zero field. The number of magnetic nanoparticles in the sample is taken from the quotient of the value of M_{S} of the sample and the standardized value of M_{S} of the particles, from the following equation:

$${m}_{magnetitenanop .} = \frac{{M}_{S} ( tissue emu )}{{M}_{S} ( normalized emu \text{/} g )}$$

Below is a brief description of the method for quantization of magnetic nanoparticle absorption into animal tissues, of the invention.

1. Method Calibration

Magnetization is measured by varying the magnetic field at room temperature resulting in a magnetization vs. magnetic field plot from which saturation magnetization is obtained (M_{S measured}) by extrapolation of high magnetic field magnetization at zero field. This is divided by known nanoparticle mass in order to obtain the value of saturation magnetization per mass unit (M_{S standardized}):

M_{S standardized}(emu/g)=M_{S measured}(emu)/m_{particles}

2. Determination of Magnetization of the Biological Sample

Magnetization of the tissue sample to be analyzed is measured, which is absorbed with the nanoparticles into magnetic fields where magnetization is linear with the field applied (usually over 3000 Oe). Saturation magnetization (M_{S tissue}) of the sample is determined by extrapolating the ordinate at the origin of linear magnetization to high magnetic fields.

3. Quantization

The number of nanoparticles is calculated from the quotient between saturation magnetization of the sample and standardized saturation magnetization of the nanoparticles.

m_{nanoparticles}(g)=M_{S tissue}(emu)/M_{S standardized}(emu/g)

The equipment for developing the method for quantization of magnetic nanoparticles of the invention consists briefly of a magnetic signal excitation and detection unit of the sample, coupled to a control and processing unit of the values obtained wherein, after the interaction of both, the value of the quantization of nanoparticles searched is obtained, which shall then be shown.

### BRIEF DESCRIPTION OF THE DRAWINGS

For a better understanding of this invention the attached drawings to which reference is made and application examples are explained below.

FIG. 1 shows Magnetization Curves vs. Magnetic Field applied (H) at different temperatures (T) of a superparamagnetic particle system with an insert showing Magnetization vs. H/T, wherein the superposition of all curves is shown.

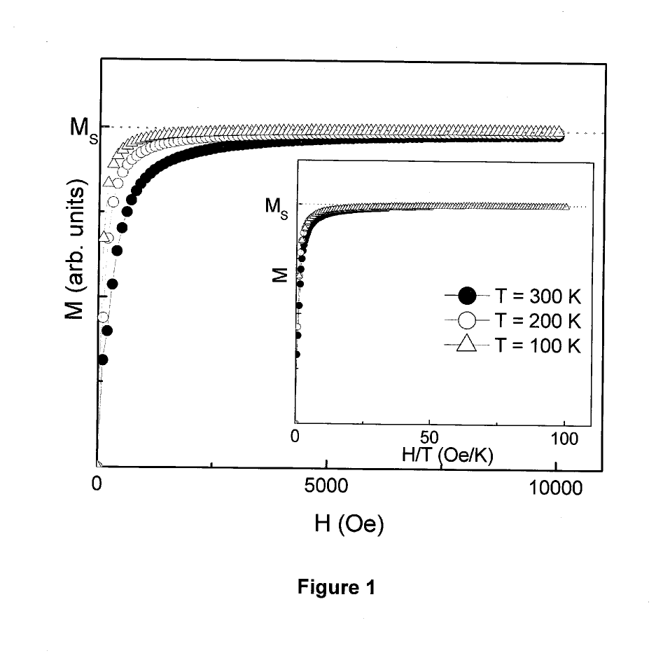

FIG. 2(a) shows characteristic magnetization curves of diamagnetic and paramagnetic materials, M(H). FIG. 2(b) shows the magnetization curve of a system consisting of a diamagnetic material+superparamagnetic nanoparticles, indicating the saturation magnetization of the nanoparticles, M_{S}, in the extrapolation of magnetization at zero magnetic field.

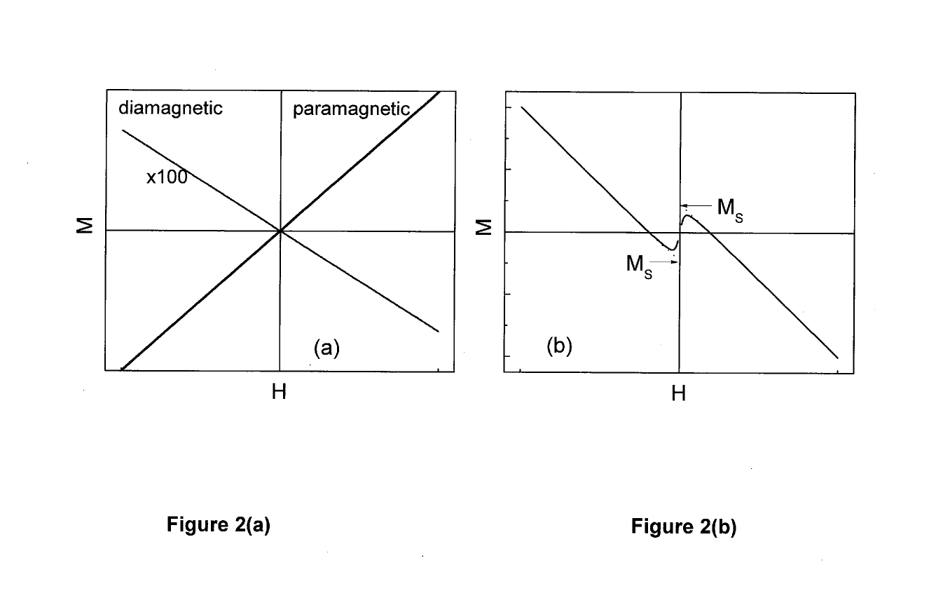

FIG. 3(a) shows the magnetization Curve, M(H), of magnetite nanoparticles 13 mm in diameter, used in this study measured at room temperature. FIG. 3(b) shows the curve M(H) of bovine muscular tissue (sample M0), showing the characteristic diamagnetic behavior.

FIGS. 4(a) and 4(b) show Curves M(H) measured at room temperature of samples M1(a) and M2(b). The superposition of diamagnetic (tissue) and superparamagnetic (nanoparticles) contributions is made evident in the curves. Dotted lines correspond to extrapolation of magnetization measured at high magnetic fields on the zero field axis, indicating saturation magnetization.

FIGS. 5(a), 5(b), 5(c) and 5(d) show mouse liver and lung Magnetization injected with a dextran-coated magnetite nanoparticle suspension showing superparamagnetic magnetization contribution (b)-(d), and the measurements M(H) of the same kinds of mouse tissues without injection (a)-(c) showing only diamagnetic behavior. The solid lines are just a guide for interpretation and the dotted lines are the extrapolation of high magnetization fields at zero field, indicating saturation magnetization.

FIG. 6 is a representation of an exemplary embodiment of the equipment of the invention consisting of a magnetic signal excitation and detection unit of the sample, coupled to a control and processing unit of the data obtained.

FIG. 7 is a scheme of the variable magnetic field generator of the equipment of the invention which allows quantization of nanoparticles in this case using an electromagnet as the generator.

FIG. 8 is a scheme of of the variable magnetic field generator of the equipment of the invention which allows quantization of nanoparticles in this case using a permanent magnet as the generator.

FIG. 9, in Table I, shows a summary of the determination of the number of magnetic nanoparticles in the various tissues.

### DETAILED DESCRIPTION OF THE INVENTION

The method of quantization of magnetic particle absorption into animal tissues of this invention comprises the following steps:

1. Method Calibration

A known number of nanoparticles is placed in the sample holder of the magnetometer, which should be made of a diamagnetic material (e.g. polymer, glass, quarz or gelatin). Nanoparticles can be in a powder state or a liquid suspension state. In the event that they are in powder state, the same is weighed before placing it in the sample holder (m_{particle}). In the event that it is a liquid suspension, its volume should be taken and the nanoparticle concentration in the suspension should be known, the mass of the nanoparticles placed in the sample holder (m_{particle}) shall be determined. Magnetization vs. magnetic field is measured at room temperature applying a known number of magnetic nanoparticles where saturation magnetization (M_{S}) is obtained by extrapolating the magnetization of high magnetic fields at zero field. This is divided by the nanoparticle mass known and determined previously in order to obtain the value of saturation magnetization per mass unit (MS standardized).

M_{S standardized}(emu/g)=M_{S measured}(emu)/m_{particles}

This calibration factor, M_{S standardized}, shall be taken as reference for any tissue measurement using the same nanoparticles, that is why this step can be made previously, particularly if normally the same kind of nanoparticles is used for working, since it can have the calibration standardized and therefore the method shall start from step 2.

2. Determination of Magnetization of the Biological Sample

The tissue samples to be analyzed can be fresh, dried, fixed, liquid tissue or any state that represents the organic tissue to be evaluated. Samples are cut in a size according to the magnetometer sample holder size, which should also be made of a diamagnetic material (e.g. polymer, glass, quartz or gelatin). The sample should be carefully weighed so that the weighing error is not preponderant in spreading the error in the relative determination of the number of particles in the tissue. In the event that the sample is liquid, weighing can be replaced by the determination of the volume thereof.

Then the tissue sample to be analyzed, which is absorbed into the nanoparticles, is placed in the magnetometer sample holder in order to determine saturation magnetization. For such purpose magnetization of samples at magnetic fields where magnetization is linear with the field applied (usually over 3000 Oe). Saturation magnetization (M_{S tissue}) of the sample is determined by extrapolating ordinate at the origin of linear magnetization at high magnetic fields.

2. Quantization

The number of nanoparticles is calculated from the quotient between saturation magnetization of the sample and standardized saturation magnetization of the nanoparticles:

m_{nanoparticles}(g)=M_{S tissue}(emu)/M_{S standardized}(emu/g)

In a particular application this determination of the Lumber of nanoparticles can be standardized with the total mass of the sample thus living an intensive characteristic of the material:

m_{nanoparticles standardized}(g_{particles}/gₜᵢₛₛᵤₑ)=m_{nanoparticles}(g)/mₛₐₘₚₗₑ(g)

This intensive characteristic would allow to determine several characteristics regarding the relationship of nanoparticles to tissues, this being essential data for developing research in the subject of medical treatments.

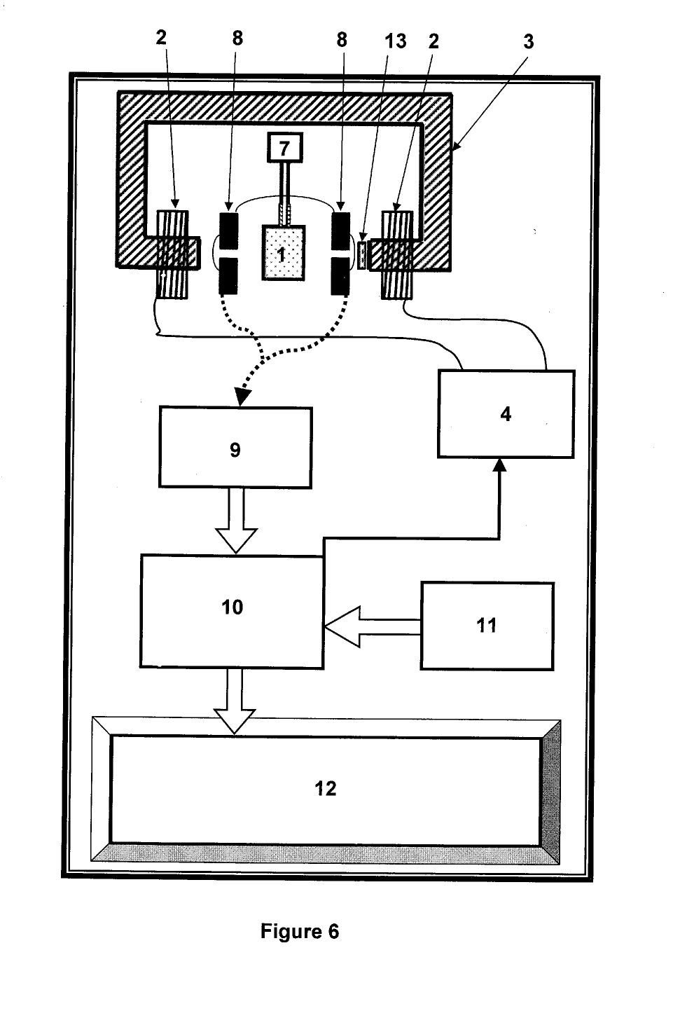

The equipment for developing magnetic nanoparticle quantization of the invention briefly consists of a magnetic signal excitation and detection unit of the sample, coupled to a control and processing unit of the data obtained. As can be seen in FIG. 6, such excitation and detection unit comprises a variable magnetic field generating device (4), wherein sample (1) is placed, with a sample holder oscillator (7), and a detecting device (8) of the magnetic signal emitted by the sample. This signal is sent to such control and processing unit, where the remaining steps of the already described method are made, by a booster which measures such signal emitted by the sample, transmitting its value to the control and processing unit (10), to which it is coupled. This unit (10) also receives information from a data entry unit (11) (particularly, sample data, weight, volume), and eventually from a magnetic field sensor (13). This control and processing unit sends a signal to the field regulator (4) which regulates the magnetic field according to the needs of the method of the invention. Once the values collected from the control and processing unit (10) are processed, the results are sent to a result display (12), completing the method of the invention, obtaining the nanoparticle quantization searched.

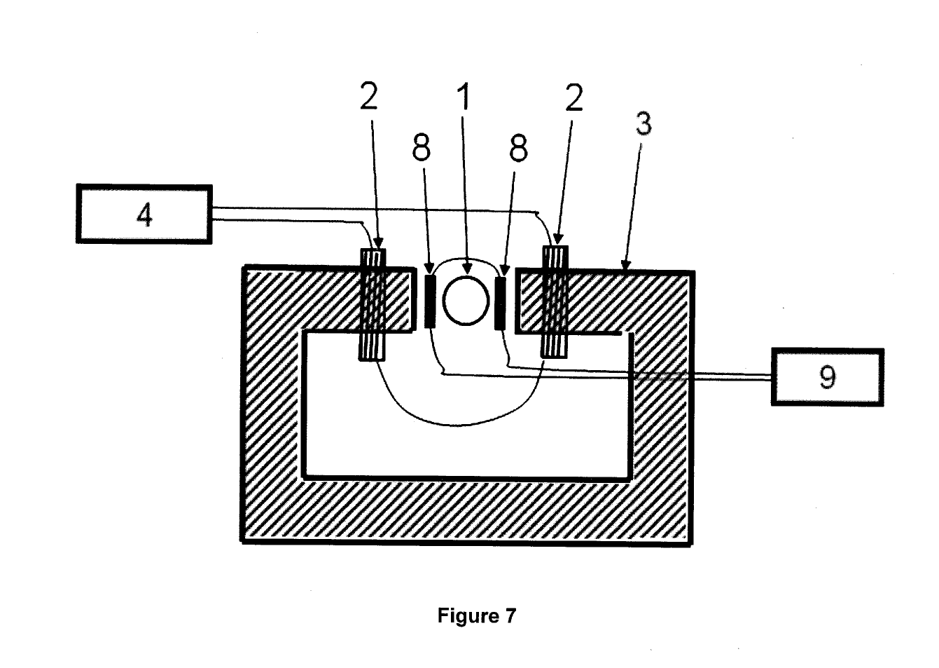

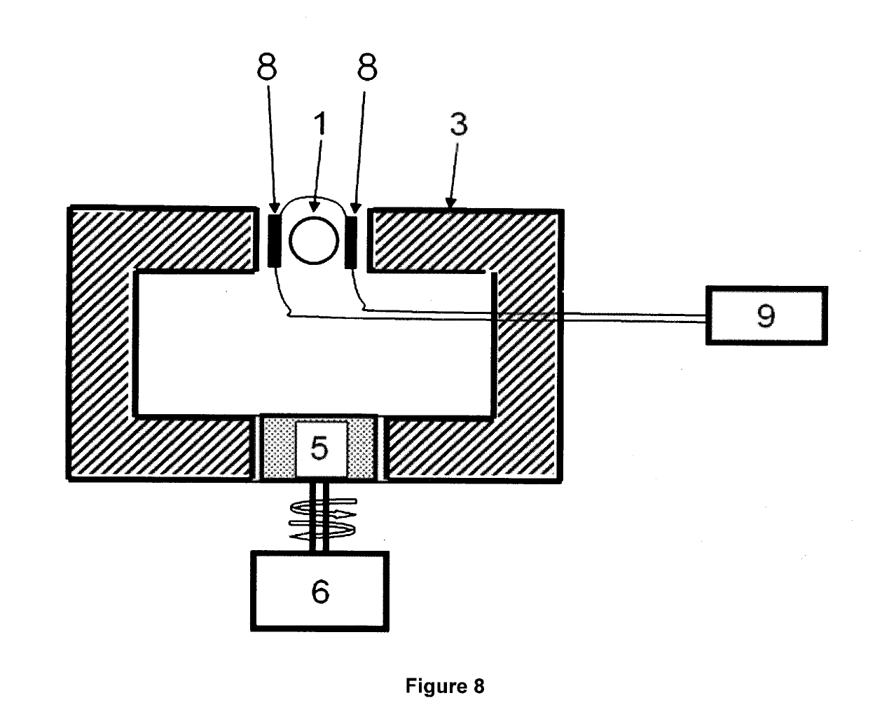

The variable magnetic field generator can be of two modes which can be seen in FIGS. 7 and 8 where sample (1) to be analyed is submitted to the variable magnetic field allowing nanoparticle quantization. In the first case, FIG. 7, it can be generated by the action of an electric current passing through a coil (2) on a magnetic material core (3), of an electromagnet kind. In this case, the magnetic field generated in the empty space between magnetic material (3) is controlled by the current from a source (4) of current delivered by coils (2). In the second case, see FIG. 8, the magnetic field useful in the zone where sample (1) would be located is generated by a permanent magnet (5) consisting of a system allowing rotation in an empty space in the magnetic material in a controlled way (6) thus functions as the field generator, playing in this case the same role as electromagnet power supply (4). The magnetic field control in the space of the sample occurs when rotating the permanent magnet. When magnet poles (5) are aligned with magnetic material (3), the magnetic field in sample region (1) is the maximum (in one or the other magnet polarity direction) and when rotating magnet (5) 90° from the first orientation a zero magnetic field is obtained in the sample zone.

In a manner common to both ways of generating the variable magnetic field we have got the vibration generating system on the sample and the magnetic signal detecting system. The sample holder oscillating longitudinal movement system, see FIG. 6, consists of a vibration generating system (7) (it can consist, for example, of a motor, a loudspeaker or a piezoelectric) coupled to the sample holder. This coupling should consist of a thread or a lock allowing to remove the sample holder to be fed with or discharged from the samples. This source holder should be made of a diamagnetic material such as polymer, glass, quartz or gelatin. The oscillating movement system (7) should work at a constant frequency (different from the mechanical resonance frequency of this portion of the equipment) and a built-in electronic system allowing to keep the amplitude of this oscillation constant during the entire measuring process (in the order of 1 millimeter). The magnetic signal detecting system is based on four coils (8) located on both sides of the magnetic material in the space kept for the sample holder, FIGS. 6, 7 and 8, induces a voltage in this coils which is proportional to the sample magnetization sought to be measured. The design of these coils takes into account that the upper coils are wound in a direction while the lower coils do so in the opposite direction. Additionally, the coils are coupled to each other if in series as indicated in FIG. 6.

FIG. 6 shows a preferred exemplary embodiment of the equipment for developing the method of quantization of magnetic nanoparticles of the invention, starting from use of an electromagnet wherein the magnetic signal excitation and detection unit has a sample holder (1) wherein the animal tissue is placed, coupled to an oscillator (7), which drives an oscillating longitudinal movement to the sample holder. The sample is sunk in the variable magnetic field generating device (4), wherein it is subject to a magnetic field, producing a signal that is sensed by a magnetic signal detector, consisting of detecting coils (8). Through a booster (9), including a voltmeter, the detected values are sent to the control and processing unit (10). This unit receives the calibration values of the magnetic nanoparticles (11), which if the same nanoparticles are kept between the tests there is no need to introduce again the values relative to the sample amount, weight or volume. In this control and processing unit the method of the invention already described continues, coupling for such purpose the magnetic field generator (4), which produces the needed variations on the sample. Once value processing has been completed they can be obtained from the result display (12), coupled to the control and processing unit (10).

The data control and processing unit (10), FIG. 6, consists of a processor, with the due electronic and digital interfaces for communication with the other units included in the equipment. This unit (10) controls the magnetic field generation, through the generator that regulates the field, whether current (4) from coils (2) or the magnet (5) rotation system (6) so as to obtain the magnetic field needed for magnetizing the sample and reaching suturation thereof. The magnetic field value existing in the sample zone (1) is incorporated to the data by a previous magnetic field calibration versus current (or rotation angle) or is recorded when measuring with magnetic field sensor (13) placed for such purpose, FIG. 6. This sensor (13) is an optional accessory of the equipment.

The magnetic signal from detecting coils (8) in the form of an alternate voltage of the same frequency as that of the vibrating system movement (7), is boosted by a booster/voltmeter (9) which responds to this working frequency. The vibrating system (7) and the booster/voltmeter (9) are synchronized regarding the frequency and movement phase and the signal from the coils. The voltage value recorded by booster/voltmeter (9) is sent to control and processing unit (10). Data processing consists of conversion of electric voltage data from booster/voltmeter (9) in sample magnetization. Using data from measurements of fields of modules over about 3000 Oe, where the same have a linear behavior, a minimum square adjustment of the linear function is made. The value of the ordinate at the origin shall correspond to saturation magnetization. With the saturation magnetization values of the sample measured and the saturation magnetization value of the particles per gram (it can be measured or a value introduced in the system), the magnetic particle mass present in the sample shall be automatically calculated.

User interface is made by a data entry unit (11) and a result display system (12). Data entry unit (11) can consist of a keyboard, a pushbutton switch, a pulsator for giving orders, touch screen, scale or another data entry system; it can be more than one of these. The result display unit (12) can consist of a monitor, video tube, alphanumeric display system, printer or another system that allows user to read the results or to make the required interface with the measuring equipment of the invention; it can be more than one of these.

### BEST MODE FOR CARRYING OUT THE EQUIPMENT OF THE INVENTION

A possible way of working of the equipment of the invention is mentioned below, by way of example.

1. Obtention of saturation magnetization of magnetic nanoparticles.

If the data of the method calibration step (M_{S standardized}) are known because it is working with the same nanoparticles, they can be introduced into the system by the data entry unit (11), being stored in the equipment data storage system.

If it is determined by a measurement of this equipment it should proceed as follows:

a) Placing in the sample holder a known number of magnetic nanoparticles (in powder, suspension or other morphology).

b) Setting the sample holder on the vibrator system stem (7) and incorporating the nanoparticle mass data into the system by the data entry unit (11).

c) Making the measurement. The control and processing unit (10) regulates the vibrator system actuation (7) and controls the field generator (4) in order to make a magnetic field variation while the data from the booster/voltmeter data (9) are obtained. Once the field variation cycle has been completed, the data are converted to magnetization and the control and processing unit (10) obtains the saturation magnetization value per gram after making a linear adjustment of the data corresponding to module fields over 3000 Oe, by dividing the ordinate at the origin by the particle mass.

d) The value of M_{S} is shown on display unit (12) and is stored in the data storage system of the equipment for later use.

2. Determination of the number of magnetic nanoparticles in the animal tissue sample.

a) It proceeds with the animal tissue like in steps a), b) and c) of the preceding item, in the measured option.

b) With the measured saturation magnetization data and the particle saturation magnetization data, the sample nanoparticle mass is automatically delivered to user, from:

m_{nanoparticles}(g)=M_{S tissue}(emu)/M_{S particles standardized}(emu/g)

c) With the measured tissue mass data, the standardized nanoparticle number with the sample total mass shall be delivered in the display unit (12), thus giving an intensive characteristic of the material.

m_{nanoparticles standardized}(g_{particles}/gₜᵢₛₛᵤₑ)=m_{nanoparticles}(g)/mₛₐₘₚₗₑ(g)

3. There is a possibility of calibrating the equipment by measuring (following the above steps) a standardized sample and thereby determining the proportionality constant of detection coil voltage (8) to sample magnetization. This operation should be done at the factory or by a specialized technician. In such event, the user should only incorporate as data the sample amount value, in the entry (11) and we would obtain as a result the quantization desired, in the display (12), therefore doing the operations mentioned in the preceding item 2.

### EXAMPLES

For a greater clarification of this invention (showing its effectiveness), and the way in which it should be taken to practice, two exemplary embodiments of the method of the invention are explained below, by using two kinds of animal tissue samples with magnetic particles. One of them consists of a muscular tissue of the bovine species injected with a known number of magnetite nanoparticles from aqueous suspensions thereof. The other sample set consists of liver and lung tissues taken from mice previously injected with aqueous nanoparticle suspensions.

Measurements of magnetization versus magnetic field (−10 kOe−10 kOe being 1 oersted=79.58 A/m in SI) were made in a commercial vibrating sample magnetometer (VSM) measured at room temperature.

Quantization of nanoparticles in bovine muscular tissue. In order to show the plausibility of using magnetic measurements with a specific method for determining the number of magnetic nanoparticles in the animal tissue, we have prepared three bovine muscular tissue samples.

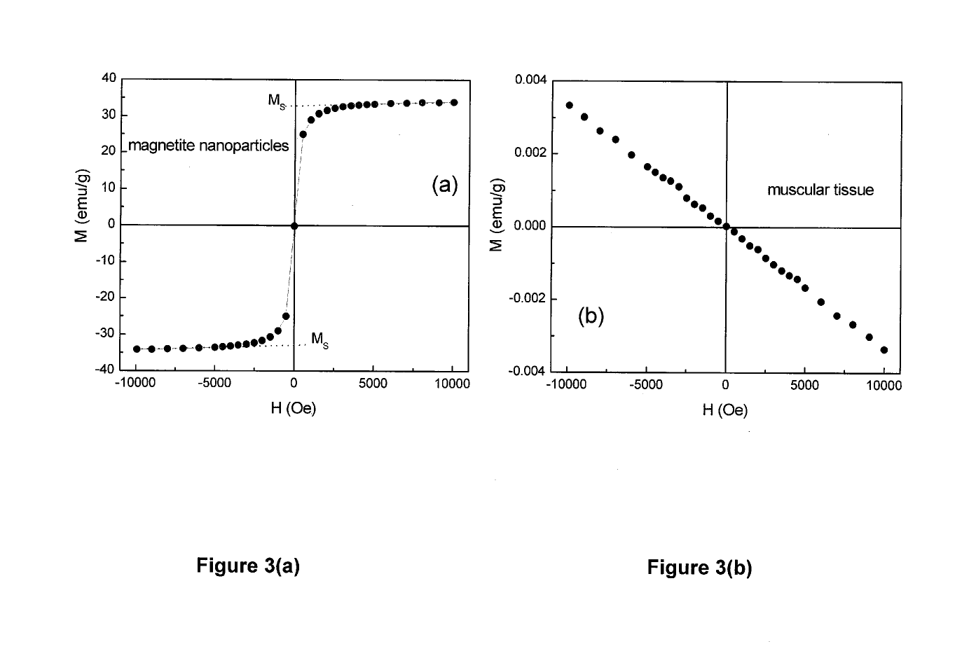

In order to make the method calibration and to check the nanoparticle magnetic signal with the tissue, a tissue sample without nanoparticles was made (sample M0). FIGS. 3(a) and 3(b) show the magnetization of the magnetite nanoparticles and the tissue sample M0 separately, wherein the superparamagnetic and diamagnetic behaviors, respectively, are shown. As shown in the preceding section, these magnetization curves are those expected for each case. From FIG. 3(a) a value of M_{S standardized}=32.8 emu/g was obtained.

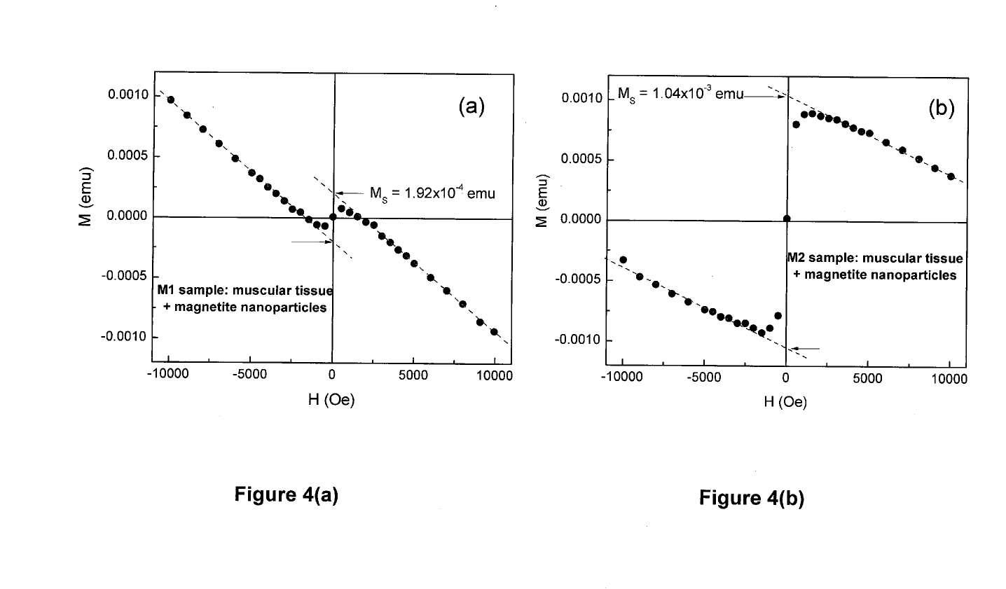

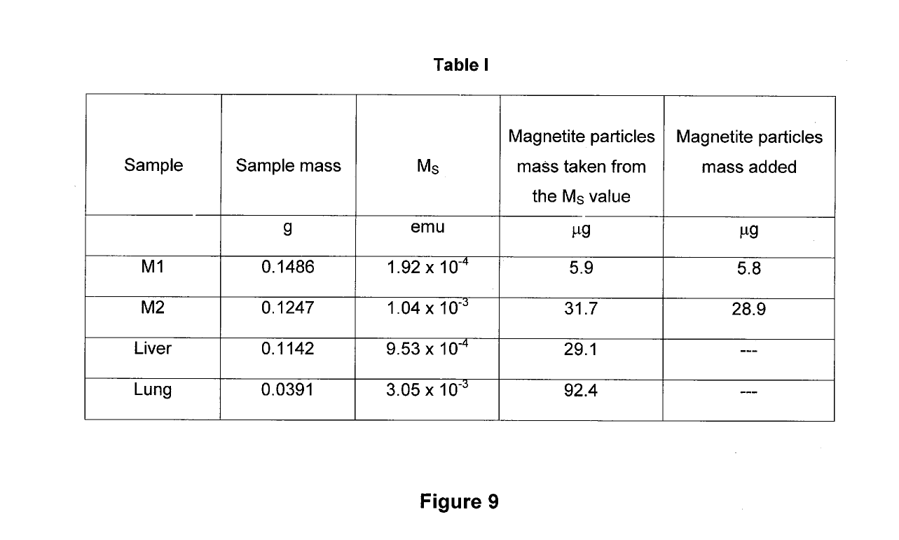

Additionally, two samples were prepared by adding an aqueous magnetite nanoparticle suspension to a muscular tissue sample. Table I in FIG. 9 summarizes the number of magnetic nanoparticles for different samples. Sample M1 was prepared by adding 22 μl of a nanoparticle suspension (2.6×20⁻⁴ g_{magnetite}/ml), equivalent to 5.8 μg (m_{particle}) of magnetite nanoparticles in 0.1486(2) g (mₜᵢₛₛᵤₑ) of muscular tissue. Sample M2 was prepared by adding 80 μl of a more concentrated nanoparticle suspension (3.6×10⁻⁴ g_{magnetite}/ml), corresponding to 28.9 μg (m_{particle}) of nanoparticles in 0.1247 g (mₜᵢₛₛᵤₑ) of muscular tissue. FIGS. 4(a) and 4(b) show the magnetization curves of samples M1 and M2, wherein the superposition of the diamagnetic and superparamagnetic contributions is evident. The extrapolation of magnetization data of high magnetic fields at zero field determines the saturation magnetization of each sample: M_{S}(M1)=1.92(2)×10⁻⁴ emu and M_{S}(M2)=1.04(2)×10⁻³ emu.

In order to obtain the mass of nanoparticles contained in the tissue sample, the quantization is made by taking into account the saturation magnetization value of magnetite nanoparticle samples, from the following equation:

$${m}_{magnetitenanop .} = \frac{{M}_{S} ( tissue emu )}{{M}_{S} ( standardized emu \text{/} g )}$$

Quantization of nanoparticles in mouse liver and lung tissues: This quantization method has been tested in the determination of the quantization of magnetite nanoparticles in various mouse tissues, previously injected with dextran-coated magnetite nanoparticles (dose of 3 mg of magnetite in the whole mouse).

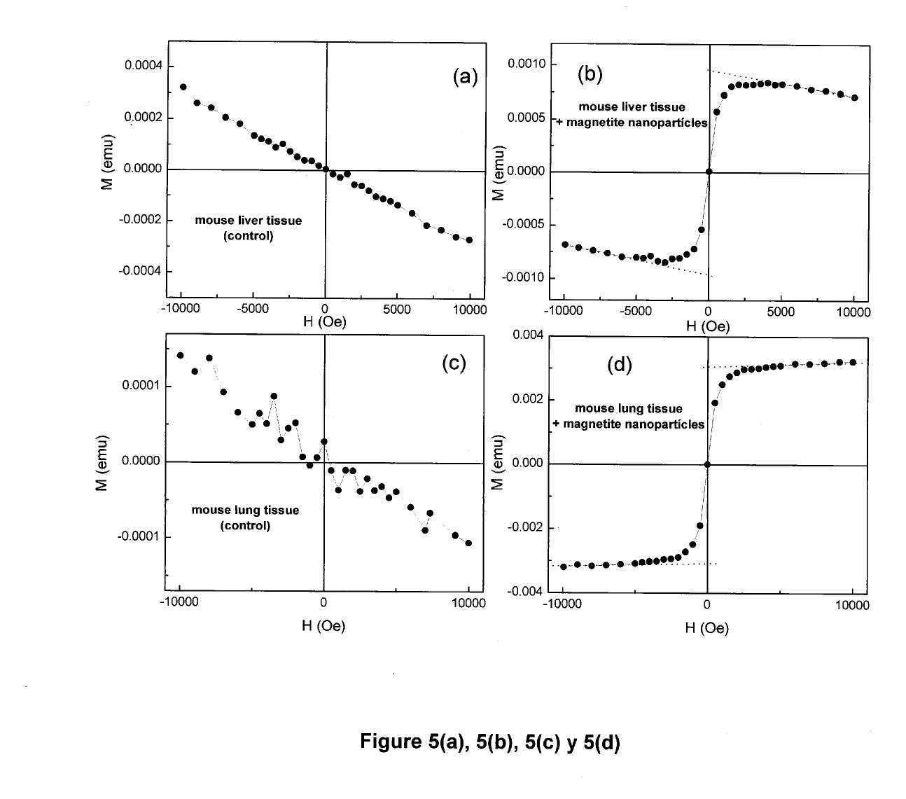

This example previously has the property of M_{S standardized} which corresponds to the nanoparticles with which work is done. FIG. 5 shows the magnetization of mouse liver and lung injected with the particles where superparamagnetic magnetization contribution is visible. In the same figure the measurements of magnetization of the same tissues (liver and lung) in a non-injected mouse sample (control animal) are plotted for comparison to the tissues with magnetite where only the diamagnetic behavior can be seen (FIGS. 5a and 5c). Table I in FIG. 9 summarizes the number of magnetic nanoparticles for the various samples. From the values of M_{S} (see the extrapolation in FIGS. 5b and 5d M_{S}(liver)=9.53×10⁻⁴ emu and M_{S}(lung)=3.05×10⁻³ emu) the magnetite nanoparticle concentration was determined in each case: 29.1 μg of magnetite in 114.2 mg of liver tissue (0.255 μg_{particles}/mgₜᵢₛₛᵤₑ) and 92.4 μg of magnetite in 39.1 mg of lung tissue (2.36 μg_{particles}/mgₜᵢₛₛᵤₑ). The method has determined the number of magnetite nanoparticles in the animal tissues, without interference from the natural presence of iron ions of tissues or blood.

1. A method of quantization of magnetic nanoparticle absorption into animal tissues, comprising the steps:
method calibration wherein nanoparticle standardized saturation magnetization is obtained;
determination of magnetization of the biological sample wherein the magnetization of the tissue sample to be analyzed, previously absorbed with the nanoparticles, is measured;
quantization of nanoparticles in the sample wherein the number of nanoparticles in the sample is calculated from the quotient between saturation magnetization of the sample, determined in step a and the standardized saturation magnetization of the nanoparticles, obtained from said previous method calibration step.

2. The method of quantization of magnetic nanoparticle absorption in animal tissues, according to claim 1, further comprising in said step of determination of the magnetization of the biological sample, the determination of the saturation magnetization of the sample by extrapolating to the ordinate at the origin on the linear magnetization plot at high magnetic fields.

3. The method of quantization of magnetic nanoparticle absorption in animal tissues, according to claim 2, wherein in said previous step of method calibration is measured, at a known number of nanoparticles, the magnetization vs. magnetic field at room temperature, from which saturation magnetization is obtained by extrapolating on the plot at zero applied magnetic field; and the standardized saturation magnetization of the division of saturation magnetization by the mass of the known number of nanoparticles.

4. The method of quantization of magnetic nanoparticle absorption in animal tissues, according to claim 3, wherein the magnetic nanoparticles are any of medical use in powder state and their weight is measured, in order to know their mass for calibration.

5. The method of quantization of magnetic nanoparticle absorption in animal tissues, according to claim 3, wherein the magnetic nanoparticles are any of medical use in a liquid suspension, their volume is measured and once their concentration is known their mass for calibration is determined.

6. The method of quantization of magnetic nanoparticle absorption in animal tissues, according to claim 3, wherein the tissue samples to be analyzed in said step of determination of the magnetization of the biological sample are in any representative tissue state, both solid and liquid.

7. The method of quantization of magnetic nanoparticle absorption in animal tissues, according to claim 3, wherein its application is to establish medical protocols.

8. The method of quantization of magnetic nanoparticle absorption in animal tissues, according to claim 3, wherein its application is to make medical treatments.

9. The method of quantization of magnetic nanoparticle absorption in animal tissues, according to claim 3, wherein its application is for medical diagnosis.

10. An equipment for quantizing magnetic nanoparticle absorption in animal tissues, comprising an excitation means which produces a magnetic signal, a magnetic signal detecting means, coupled to a means of control and processing of the values of said signal, for quantization, one or more data entry devices and one or more result display means.

11. An equipment for quantizing the magnetic nanoparticle absorption in animal tissues, according to claim 10, further comprising in such excitation means, a variable field generating means and a vibration generating means coupled to the sample holder, containing the animal sample and said magnetic signal detecting means is coupled to a voltmeter/booster.

12. The equipment for quantizing magnetic nanoparticle absorption in animal tissues, according to claim 11, wherein said variable field generating means is an electromagnet, and said magnetic signal detecting means are series connected coils.

13. The equipment for quantizing magnetic nanoparticle absorption in animal tissues, according to claim 11, wherein said variable field generating means is a permanent magnet, and said magnetic signal detecting means are series connected coils.

14. The equipment for quantizing magnetic nanoparticle absorption in animal tissues, according to claim 11, further comprising a magnetic field sensor incorporated in said magnetic excitation and detection means making a previous calibration of the variable magnetic field.

15. The equipment for quantizing magnetic nanoparticle absorption in animal tissues, according to claim 10, wherein one of said result display means is a printing device.

16. The equipment for quantizing magnetic nanoparticle absorption in animal tissues, according to claim 10, wherein one of said result display means is a display.

17. The equipment for quantizing magnetic nanoparticle absorption in animal tissues, according to claim 10, wherein one of said data entry devices is a pulsating means.

18. The equipment for quantizing magnetic nanoparticle absorption in animal tissues, according to claim 10, wherein one of said data entry devices is a keyboard.

19. The equipment for quantizing magnetic nanoparticle absorption in animal tissues, according to claim 10, wherein one of said data entry devices is a scale.

20. The equipment for quantizing magnetic nanoparticle absorption in animal tissues, according to claim 10, wherein one of said data entry devices is a touch screen.
